(19) United States
(12) Patent Application Publication
(10) Pub. No.: US 2024/0332311 A1
(43) Pub. Date: Oct. 3, 2024

(54) ARRAY SUBSTRATE AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventors: Zhixiang CHEN, Shenzhen (CN); Tianhong WANG, Shenzhen (CN)

(21) Appl. No.: 17/615,364

(22) PCT Filed: Oct. 27, 2021
(86) PCT No.: PCT/CN2021/126693

§ 371 Date: Jun. 5, 2024

(30) Foreign Application Priority Data
Oct. 13, 2021 (CN) 202111191008.7

(51) Int. Cl. H01L 27/12

(52) U.S. Cl. CPC H01L 27/124

(57) ABSTRACT

An array substrate and a display panel are provided. The array substrate provided in the embodiments of the present disclosure includes a plurality of gate on array (GOA) units, a plurality of clock signal lines, and a plurality of communication lines. A winding area is provided between the clock signal lines and the GOA units. The communication lines are bent in the winding area. By means of the winding design, lateral capacitances of the communication lines that are on a same side are caused to be same. In this way, the problem that the lateral capacitances generated by the communication lines in different rows and surrounding traces are different is resolved.

### CROSS REFERENCE TO RELATED APPLICATIONS

This application is a US national phase application based upon an International Application No. PCT/CN2021/126693, filed on Oct. 27, 2021, which claims priority to Chinese Patent Application No. 202111191008.7, filed on Oct. 13, 2021. The entire disclosures of the aforementioned applications are incorporated herein by reference in their entireties.

### TECHNICAL FIELD

The present disclosure relates to the field of display technologies, and in particular, to an array substrate and a display panel.

### BACKGROUND

In panel products, the normal display of an active display area (active area, AA) is jointly controlled by a gate line and a data line. The gate line controls the switching state of a thin film transistor (TFT) in the pixel, and the data line transmits voltage signals required by the pixel.

In gate on array (GOA) products, a gate line signal is transferred from a bus line to a gate drive unit (GOA Circuit), and then inputted to the gate line in the AA through the GOA circuit. CK in the bus line is usually ordered in sequence from inside to outside. Taking 8 clock signals as an example, the CK8 at the outermost periphery needs to cross CK7-CK1 to be connected to the GOA unit, and the CK1 does not need to cross other CK traces. Therefore, there are differences in resistances and capacitances between CK1-8, which in turn leads to differences in GN waveforms of two adjacent gate lines. Because the differences in the resistance and capacitance of the adjacent CK traces cause differences in scanning signal waveforms outputted by the adjacent two gate lines, a difference in charging is caused, resulting in an obvious difference in brightness. Therefore, periodic horizontal dense lines are generated on the product.

During the research and practice of the prior art, the inventor of the present disclosure found that in the actual product design, the capacitance and resistance are compensated and matched by means of winding. However, according to the existing winding compensation method, it is easy to increase the lateral capacitance that does not exist originally.

### SUMMARY

Embodiments of the present disclosure provide an array substrate and a display panel, so as to improve the difference in lateral capacitance between traces.

An embodiment of the present disclosure provides an array substrate, including:
a plurality of gate on array (GOA) units;
a plurality of clock signal lines, disposed on a side of the GOA units and arranged in sequence in a first direction; and
a plurality of communication lines, wherein one of the communication lines is correspondingly connected to one of the clock signal lines and one of the GOA units, wherein
a winding area is provided between the clock signal lines and the GOA units, each communication line includes a first part, a winding part, and a second part connected in sequence, the first part is connected to each clock signal line, the second part is connected to each GOA unit, and the winding part is disposed in the winding area.

The winding part includes a plurality of first connection lines, a plurality of second connection lines, and a plurality of bent connection lines. Each bent connection line connects each first connection line to each second connection line. The each first connection line is disposed opposite to the each clock signal line, and the each second connection line is disposed opposite to the GOA unit.

Lateral capacitances formed by the plurality of first connection lines and the clock signal lines are equal, and/or lateral capacitances formed by the plurality of second connection lines and the GOA units are equal.

Optionally, in some embodiments of the present disclosure, in a second direction that intersects with the first direction, the plurality of first connection lines have a same length, and/or the plurality of second connection lines have a same length.

Optionally, in some embodiments of the present disclosure, in the first direction, distances between the plurality of first connection lines and the clock signal lines are equal, and/or distances between the plurality of second connection lines and the GOA units are equal.

Optionally, in some embodiments of the present disclosure, the plurality of communication lines have a same length.

Optionally, in some embodiments of the present disclosure, the each first connection line includes a first trace, a second trace, and a third trace, the first trace is disposed on a side away from the each bent connection line, the second trace is spaced apart from the first trace, the second trace is connected to the each bent connection line, the third trace is connected between the first trace and the second trace, and the first trace and the second trace have a same length or different lengths.

Optionally, in some embodiments of the present disclosure, the each second connection line includes a first wire, a second wire, and a third wire, the first wire is disposed on a side away from the each bent connection line, the second wire and the first wire are disposed in parallel and spaced apart by a spacing, the second wire is connected to the each bent connection line, the third wire is connected between the first wire and the second wire, and the first wire and the second wire have a same length or different lengths.

Optionally, in some embodiments of the present disclosure, the each communication line includes one first connection line, one second connection line, and one bent connection line.

Optionally, in some embodiments of the present disclosure, the each communication line includes at least two first connection lines, at least two second connection lines, and one bent connection line.

Optionally, in some embodiments of the present disclosure, the each bent connection line includes a plurality of bent units connected in sequence, and the bent units are respectively connected to the first connection lines and the second connection lines using traces.

Optionally, in some embodiments of the present disclosure, at least one parallel trace is further connected to the bent units, and the parallel trace is disposed in parallel with the each bent connection line.

Optionally, in some embodiments of the present disclosure, each clock signal line is connected to the plurality of communication lines, and a set of communication lines including at least one communication line are connected to the clock signal lines in sequence in a direction in which the clock signal lines are disposed.

Optionally, in some embodiments of the present disclosure, in each set of communication lines, in a second direction that intersects the first direction, the first parts are increasingly larger, and bending lengths of the bent connection lines are increasingly smaller.

Optionally, in some embodiments of the present disclosure, in each set of communication lines, in a second direction that intersects the first direction, the first parts are increasingly larger, and bending spacings between the bent connection lines are increasingly smaller.

Correspondingly, an embodiment of the present disclosure further provides a display panel, including:
an array substrate, including
a plurality of GOA units, a plurality of clock signal lines, and a plurality of communication lines, wherein the plurality of clock signal lines are disposed on a side of the GOA units and are arranged in sequence in a first direction, one of the communication lines is correspondingly connected to one of the clock signal lines and one of the GOA units,
a winding area is provided between the clock signal lines and the GOA units, each communication line includes a first part, a winding part, and a second part connected in sequence, the first part is connected to each clock signal line, the second part is connected to each GOA unit, and the winding part is disposed in the winding area.

The winding part includes a plurality of first connection lines, a plurality of second connection lines, and a plurality of bent connection lines. Each bent connection line connects each first connection line to each second connection line. The each first connection line is disposed opposite to the each clock signal line, and the each second connection line is disposed opposite to the GOA unit.

Lateral capacitances formed by the plurality of first connection lines and the clock signal lines are equal, and/or lateral capacitances formed by the plurality of second connection lines and the GOA units are equal; and a counter substrate, disposed opposite to the array substrate, wherein an electrode is disposed on the counter substrate corresponding to the communication lines and the clock signal lines.

Optionally, in some embodiments of the present disclosure, in a second direction that intersects with the first direction, the plurality of first connection lines have a same length, and/or the plurality of second connection lines have a same length.

Optionally, in some embodiments of the present disclosure, in the first direction, distances between the plurality of first connection lines and the clock signal lines are equal, and/or distances between the plurality of second connection lines and the GOA units are equal.

Optionally, in some embodiments of the present disclosure, the each first connection line includes a first trace, a second trace, and a third trace, the first trace is disposed on a side away from the each bent connection line, the second trace is spaced apart from the first trace, the second trace is connected to the each bent connection line, the third trace is connected between the first trace and the second trace, and the first trace and the second trace have a same length or different lengths.

Optionally, in some embodiments of the present disclosure, the each second connection line includes a first wire, a second wire, and a third wire, the first wire is disposed on a side away from the each bent connection line, the second wire and the first wire are disposed in parallel and spaced apart by a spacing, the second wire is connected to the each bent connection line, the third wire is connected between the first wire and the second wire, and the first wire and the second wire have a same length or different lengths.

Optionally, in some embodiments of the present disclosure, the each bent connection line includes a plurality of bent units connected in sequence, and the bent units are respectively connected to the first connection lines and the second connection lines using traces.

Optionally, in some embodiments of the present disclosure, at least one parallel trace is further connected to the bent units, and the parallel trace is disposed in parallel with the each bent connection line.

Embodiments of the present disclosure provide an array substrate and a display panel. The array substrate provided in the embodiments of the present disclosure includes a plurality of gate on array (GOA) units, a plurality of clock signal lines, and a plurality of communication lines. The plurality of communication lines have a same length, and a winding area is provided between the clock signal lines and the GOA units. The communication lines are bent in the winding area. In the winding area, lateral capacitances of the plurality of communication lines that are on at least one side close to the clock signal lines or close to the GOA units are same. By means of the winding design, lateral capacitances of the communication lines that are on a same side are caused to be same. In this way, the problem that the lateral capacitances generated by the communication lines in different rows and surrounding traces are different is resolved. In addition, the communication lines are wound in the winding area, so that total lengths of the communication lines in different rows are same, and the problem of inconsistency in resistances and capacitances of the communication lines in different rows is also resolved, thereby alleviating the problem of open and concealed lines of the panel.

### DESCRIPTION OF THE DRAWINGS

To describe the technical solutions in the embodiments of the present disclosure more clearly, the following briefly describes accompanying drawings required for describing the embodiments. Apparently, the accompanying drawings in the following descriptions show merely some embodiments of the present disclosure, and a person skilled in the art may still derive other accompanying drawings from these accompanying drawings without creative efforts.

FIG. 1 is a schematic diagram of a first structure of an array substrate according to an embodiment of the present disclosure.

FIG. 2 is a schematic diagram of a first structure of communication lines in an array substrate according to an embodiment of the present disclosure.

FIG. 3 is a schematic diagram of a second structure of communication lines in an array substrate according to an embodiment of the present disclosure.

FIG. 4 is a schematic diagram of a third structure of communication lines in an array substrate according to an embodiment of the present disclosure.

FIG. 5 is a schematic diagram of a second structure of an array substrate according to an embodiment of the present disclosure.

FIG. 6 is a schematic diagram of a fourth structure of communication lines in an array substrate according to an embodiment of the present disclosure.

FIG. 7 is a schematic diagram of a fifth structure of communication lines in an array substrate according to an embodiment of the present disclosure.

FIG. 8 is a schematic diagram of a sixth structure of communication lines in an array substrate according to an embodiment of the present disclosure.

FIG. 9 is a schematic diagram of a third structure of an array substrate according to an embodiment of the present disclosure.

FIG. 10 is a schematic diagram of a fourth structure of an array substrate according to an embodiment of the present disclosure.

FIG. 11 is a schematic diagram of a structure of a display panel according to an embodiment of the present disclosure.

### DETAILED DESCRIPTION

The technical solutions in the embodiments of the present disclosure are clearly and completely described below with reference to the accompanying drawings in the embodiments of present disclosure. Apparently, the described embodiments are merely some rather than all of the embodiments of present disclosure. All other embodiments obtained by a person skilled in the art based on the embodiments of the present disclosure without creative efforts shall fall within the protection scope of the present disclosure. In addition, it should be understood that the specific implementations described herein are merely used for describing and illustrating the present disclosure, but are not intended to limit the present disclosure. In the present disclosure, without the contrary explanation, the directional terms such as “above” and “below” generally refer to “above” and “below” in actual use or a working state of a device, and specifically refer to drawing directions of the corresponding accompanying drawings; and “inside” and “outside” are relative to the contour of the device.

The embodiments of the present disclosure provide an array substrate and a display panel. Detailed descriptions are separately provided below. It should be noted that the description sequence of the following embodiments is not intended to limit preference orders of the embodiments.

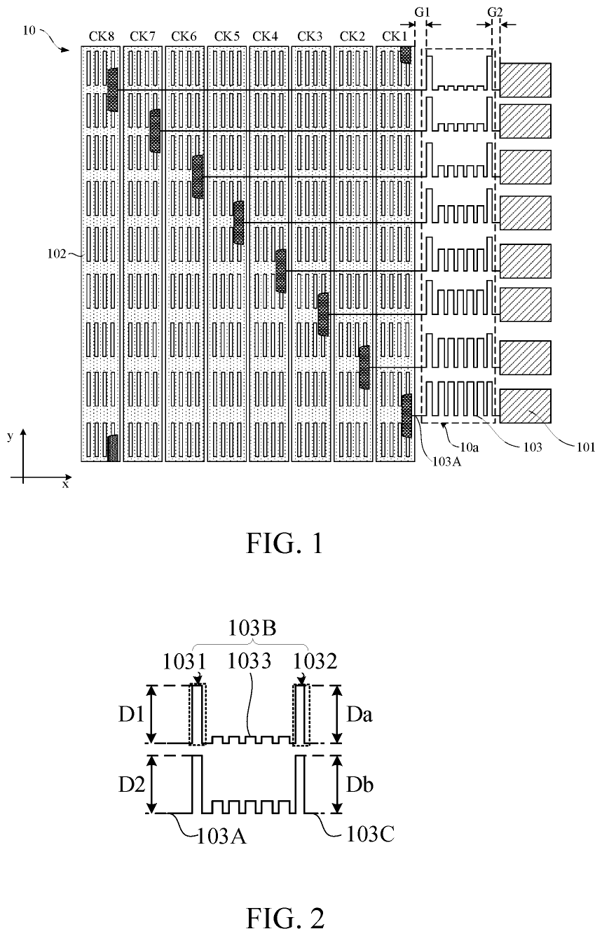

An embodiment of the present disclosure provides an array substrate. Refer to FIG. 1 and FIG. 2. FIG. 1 is a schematic diagram of a first structure of an array substrate according to an embodiment of the present disclosure. FIG. 2 is a schematic diagram of a first structure of communication lines in an array substrate according to an embodiment of the present disclosure. An array substrate 10 includes a plurality of gate on array (GOA) units 101, a plurality of clock signal lines 102, and a plurality of communication lines 103. The plurality of clock signal lines 102 are disposed on a side of the GOA units 101 and are arranged in sequence in a first direction x. It should be noted that the first direction x is a direction extending along an axis x in the figure. In the embodiment of the present disclosure, the first direction x is used for description. One communication line 103 is correspondingly connected to one clock signal line 102 and one GOA unit 101. A winding area 10a is provided between the clock signal lines 102 and the GOA units 101. The communication lines 103 include a first part 103A, a winding part 103B, and a second part 103C connected in sequence. The first part 103A is connected to the clock signal lines 102. The second part 103C is connected to the GOA units 101. The winding part 103B is disposed in the winding area 10a.

The winding part 103B includes a first connection line 1031, a second connection line 1032, and a bent connection line 1033. The bent connection line 1033 connects the first connection line 1031 to the second connection line 1032. The first connection line 1031 is disposed opposite to the clock signal lines 102. The second connection line 1032 is disposed opposite to the GOA units 101. Lateral capacitances formed by the plurality of first connection lines 1031 and the clock signal lines 102 are equal, and/or lateral capacitances formed by the plurality of second connection lines 1032 and the GOA units 101 are equal.

In detail, an array substrate 10 having 8 clock signals is used as an example for description in FIG. 1. The array substrate 10 provided in an embodiment of the present disclosure does not limit a quantity of clock signals. For example, the array substrate 10 having 12 clock signals may also be applied, or the array substrate 10 having 16 clock signals may be applied. The clock signal lines 102 of the array substrate having 8CK include CK1, CK2, CK3, CK4, CK5, CK6, CK7, and CK8. The resistances and capacitances of the communication lines 103 of CK1-CK8 are equal, which is realized by means of winding compensation of the communication lines 103 in the winding area 10a. Since the CK8 requires to cross traces of CK1 to CK7 to be connected to the GOA unit 101, and the CK1 does not require to cross other clock signal lines 102, if winding compensation is not performed, the CK1 has a shortest trace, and the CK8 has a longest trace. This may cause differences in the capacitances and resistances of the clock signal lines 102 of CK1-CK8. However, if the winding design is performed, the communication lines 103 generate a length in a second direction y, thereby increasing an area of the communication lines 103 directly facing the surrounding traces in the second direction y. Therefore, the lateral capacitance is easily generated between the winding area 10a and the GOA unit 101 or the clock signal line 102. The second direction y is a direction extending along an axis y in the figure. In the embodiment of the present disclosure, the direction is expressed as the second direction y. In the accompanying drawings of the embodiments of the present disclosure, the first direction x and the second direction y are perpendicular to each other as an example, which is not a limitation on the first direction x and the second direction y. The first direction x intersects with the second direction y.

The lateral capacitance refers to the capacitance generated in the area of the communication lines 103 directly facing the traces in the GOA units 101 or the clock signal lines 102. Generally, the winding area of the CK1 is larger and the winding area of the CK8 is smaller, so that the lateral capacitances generated between the CK1-CK8 and the GOA units 101 and the clock signal lines 102 are different. The differences in the lateral capacitances may also cause the difference in waveforms of outputted scan signals, and then cause the problem of open and concealed lines for the panel display.

The communication lines 103 and the clock signal lines 102 are disposed on different layers. The opposite arrangement of the first connection line 1031, the second connection line 1032, and the clock signal line 102 in the communication lines 103 refers to the opposite arrangement on different layers.

An embodiment of the present disclosure provides an array substrate 10. The array substrate 10 includes a plurality of GOA units 101, a plurality of clock signal lines 102, and a plurality of communication lines 103. A winding area 10a is provided between the clock signal lines 102 and the GOA units 101. The communication lines 103 are bent in the winding area 10a. Each communication line 103 includes at least one first connection line 1031, at least one second connection line 1032, and a bent connection line 1033. The first connection line 1031 is disposed on a side of the winding area 10a that is close to the clock signal lines 102, and is disposed opposite to the clock signal lines 102. The second connection line 1032 is disposed on a side of the winding area 10a that is close to the GOA units 101, and is disposed opposite to the GOA units 101. The bent connection line 1033 connects the first connection line 1031 to the second connection line 1032. Lateral capacitances formed by the plurality of first connection lines 1031 and the clock signal lines 102 are equal, and/or lateral capacitances formed by the plurality of second connection lines 1032 and the GOA units 101 are equal.

The communication line 103 refers to a bus, and may also be referred to as a bus line. The bus line is a public communication trunk that transmits information between various functional components, and is a transmission harness composed of wires. In the GOA display product, a clock signal from the clock signal line 102 is transmitted to the GOA unit 101 via the communication line 103, and then the GOA unit 101 outputs a scan signal to a gate line of an active display area of the panel.

In the embodiment of the present disclosure, lateral capacitances formed by the plurality of first connection lines 1031 and the clock signal lines 102 are equal, and/or lateral capacitances formed by the plurality of second connection lines 1032 and the GOA units 101 are equal. The lateral capacitance is mainly affected by relative areas and spacings of two adjacent traces. Optionally, in the second direction y that intersects with the first direction x, the plurality of first connection lines 1031 have a same length, and/or the plurality of second connection lines 1032 have a same length.

When a thickness of the metal layer film remains unchanged, the lateral capacitance is completely positively correlated with a length of the adjacent traces directly facing each other. Therefore, it may be ensured that the communication lines 103 on a same side have a same length and also have a same lateral capacitance. In this way, in the winding area 10a, the communication lines 103 on the side close to the clock signal lines 102 are designed to have a same bending length, or the communication lines 103 on the side close to the GOA units 101 have a same bending length, so that the lateral capacitances of the communication lines 103 on at least one side are caused to be same. Accordingly, the problem that the lateral capacitances generated by the communication lines 103 in different rows and surrounding traces are different is resolved.

As shown in FIG. 2, FIG. 2 is a schematic diagram of communication lines 103 in a first row and a second row that are partially enlarged in FIG. 1. In FIG. 2, a bending length of first connection lines 1031 in the first row is D1, and a bending length of the first connection lines 1031 in the second row is D2. D1 is same as D2. In this case, a bending length of second connection lines 1032 in the first row may be different from a bending length of the second connection lines 1032 in the second row. Alternatively, still refer to FIG. 2, in FIG. 2, a bending length of the second connection lines 1032 in the first row is Da, and a bending length of the second connection lines 1032 in the second row is Db. Da has a same length as Db. In this case, the first connection lines 1031 in the first row have a same bending length as the first connection lines 1031 in the second row.

Optionally, still refer to FIG. 2, in the winding area 10a, the bending lengths of the plurality of first connection lines 1031 are same, and the plurality of second connection lines 1032 are same. That is to say, D1 has a same length as D2, and Da has a same length as Db.

Optionally, in some embodiments, in the winding area 10a, the bending lengths of the plurality of first connection lines 1031 are all same as that of the plurality of second connection lines 1032. That is to say, the lengths of D1, D2, Da, and Db may be all same.

In the embodiment shown in FIG. 2, the lengths of D1, D2, Da, and Db being all same is used as an example, but is not a limitation on the present disclosure. In the embodiment of the present disclosure, it is only necessary to ensure that the bending lengths on a same side are same, so that the influence of the lateral capacitance on the pulse height of the scan signal can be improved.

Optionally, in the first direction x, distances G1 between the plurality of first connection lines 1031 and the clock signal lines 102 are equal, and/or distances G2 between the plurality of second connection lines 1032 and the GOA units 101 are equal.

Optionally, the plurality of communication lines 103 have a same length. The communication lines 103 are wound in the winding area 10a, so that total lengths of the communication lines 103 in different rows are same, and the problem of inconsistency in resistances and capacitances of the communication lines 103 in different rows is also resolved. In the array substrate 10 provided in the embodiment of the present disclosure, by means of the design of the bending method of the communication lines 103, the problem of the open and concealed lines of the panel can be improved.

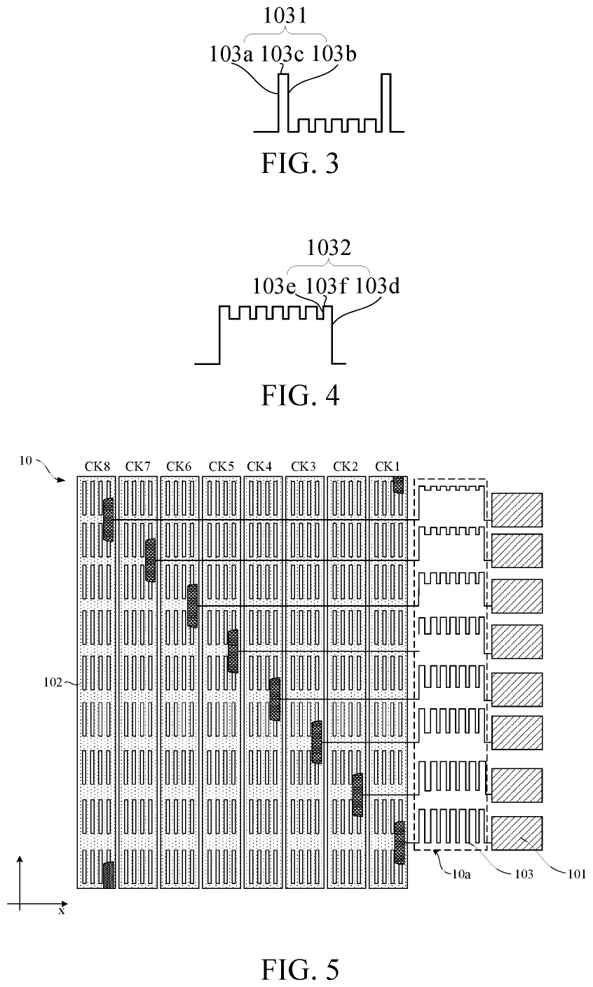

Optionally, refer to FIG. 3. FIG. 3 is a schematic diagram of a second structure of communication lines in an array substrate according to an embodiment of the present disclosure. Each first connection line 1031 includes a first trace 103a, a second trace 103b, and a third trace 103c. The first trace 103a is disposed on a side away from the each bent connection line 1033. The second trace 103b and the first trace 103a are disposed in parallel and spaced apart by a spacing. The second trace 103b is connected to the bent connection line 1033. The third trace 103c connects the first trace 103a to the second trace 103b. Optionally, the first trace 103a and the second trace 103b have a same length or different lengths. FIG. 1 and FIG. 3 show a structure in which the first trace 103a and the second trace 103b have a same length.

Optionally, refer to FIG. 4. FIG. 4 is a schematic diagram of a third structure of communication lines in an array substrate according to an embodiment of the present disclosure. Optionally, each second connection line 1032 includes a first wire 103d, a second wire 103e, and a third wire 103f. The first wire 103d is disposed on a side away from the each bent connection line 1033. The second wire 103e and the first wire 103d are disposed in parallel and spaced apart by a spacing. The second wire 103e is connected to the bent connection line 1033. The third wire 103f connects the first wire 103d to the second wire 103e. Optionally, the first wire 103d and the second wire 103e have a same length or different lengths. FIG. 1 and FIG. 3 show a structure in which the first wire 103d the second wire 103e have a same length.

Referring to FIG. 4 and FIG. 5 together, FIG. 5 is a schematic diagram of a second structure of an array substrate according to an embodiment of the present disclosure. A difference between the embodiment shown in FIG. 5 and the embodiment shown in FIG. 1 is that the first trace 103a and the second trace 103b have different lengths in FIG. 5.

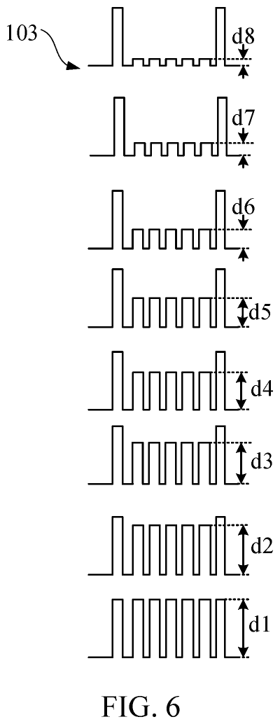

Optionally, each clock signal line 102 is connected to a plurality of communication lines 103. A set of communication lines 103 including at least one communication line 103 are connected to the clock signal lines 102 in sequence in a direction in which the clock signal lines 102 are disposed. That is to say, the communication lines 103 are connected to the clock signal lines 102 in sequence in a cyclic arrangement. Referring to FIG. 1 and FIG. 6, FIG. 1 shows an arrangement mode of the communication lines 103 in one cycle. In a next cycle, the communication line 103 is repeatedly connected to the clock signal line 102 in the connection sequence shown in FIG. 1. It may be understood that, in different situations, a sequence in which the communication lines 103 are connected may be selected according to the clock signal line 102 that is to be connected to the GOA unit 101. Certainly, after the sequence in which the communication lines 103 are connected is changed, the bending method of the communication lines 103 also requires to be changed accordingly, so as to ensure that the total lengths of the communication lines 103 connected to different clock signal lines 102 are same.

Optionally, refer to FIG. 1 and FIG. 6. FIG. 6 is a schematic diagram of a fourth structure of communication lines in an array substrate according to an embodiment of the present disclosure. In each set of communication lines 103, in a second direction y that intersects the first direction x, the first parts 103A are increasingly larger, and bending lengths of the bent connection lines 1033 are increasingly smaller. In FIG. 4, the 8CK is still used as an example for description. The bending lengths of the bent connection lines 1033 correspondingly connected to CK1, CK2, CK3, CK4, CK5, CK6, CK7, and CK8 are respectively d1, d2, d3, d4, d5, d6, d7, and d8. Since each set of communication lines 103 are connected to the clock signal lines 102 in sequence from CK8 to CK1 in a direction in which the clock signal lines 102 are disposed, an order of sizes of the bending length is d8<d7<d6<d5<d4<d3<d2<d1. d8 may be 0. That is to say, the bent connection line 1033 of CK8 may be not bent and directly connects the first connection line 1031 to the second connection line 1032 of CK8.

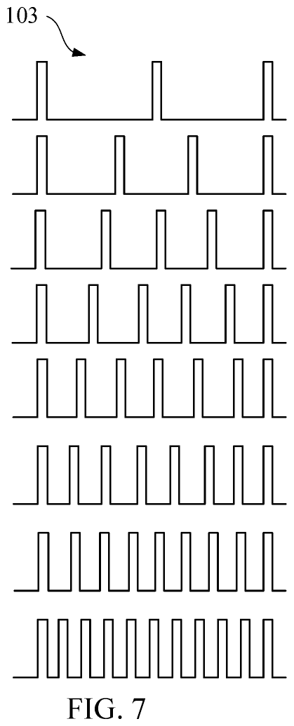

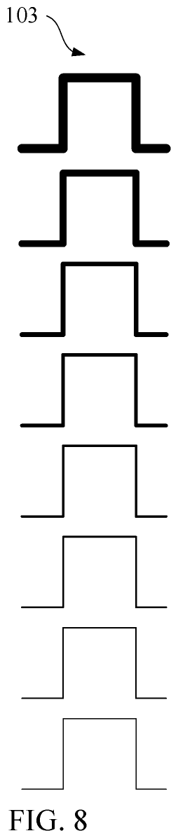

Optionally, refer to FIG. 1 and FIG. 7. FIG. 7 is a schematic diagram of a fifth structure of communication lines in an array substrate according to an embodiment of the present disclosure. In each set of communication lines 103, in the second direction y that intersects the first direction x, the first parts 103A are increasingly larger, and bending spacings of the bent connection lines 1033 are increasingly smaller. In FIG. 7, the 8CK is still used as an example for description. Since the lengths of the communication lines 103 correspondingly connected to CK1, CK2, CK3, CK4, CK5, CK6, CK7, and CK8 that require to be wound are reduced in sequence, the bending spacing of the bent connection line 1033 connected to CK1 is the smallest, and the bending spacing of the bent connection line 1033 connected to CK8 is the largest.

The above embodiments are all described using a sequence in which the communication lines 103 are connected to the clock signal lines 102 of CK8 to CK1 in sequence as an example. When the sequence in which the communication lines are connected to the clock signal lines 102 requires to be changed, the bending area, the bending length, or bending density of the communication lines 103 are all to be changed accordingly. In addition, in the above embodiment, any of the bending area, the bending length, and the bending density is increased or decreased. Alternatively, any two or three of the bending area, the bending length, and the bending density are to be designed. The above embodiments are described using these winding methods as examples. In fact, there may be other winding methods as long as the total lengths of the communication lines in each row are same.

Optionally, refer to FIG. 1 and FIG. 8. FIG. 8 is a schematic diagram of a sixth structure of communication lines in an array substrate according to an embodiment of the present disclosure. Since the magnitude of the resistance is inversely proportional to the area of the trace, in order to match the resistances of the communication lines 103 between different rows when it is ensured that the lengths of the communication lines 103 are same, a width of the communication line 103 having a larger length may also be appropriately increased, so as to reduce the resistance of the communication line 103. Similarly, the width of the communication line 103 having a smaller length may be appropriately reduced to increase the resistance of the communication line 103. Accordingly, the problem of uneven resistances between the communication lines 103 in different rows is reduced. For example, a plurality of communication lines 103 are connected to one clock signal line 102. A set of communication lines 103 including at least one communication line 103 are connected to the clock signal lines 102 in sequence in a direction in which the clock signal lines 102 are disposed. In this case, the communication line 103 connected to CK1 has a smallest line width, and the communication line 103 connected to CK8 has a largest line width, so as to match the resistances of the communication lines 103 in different rows.

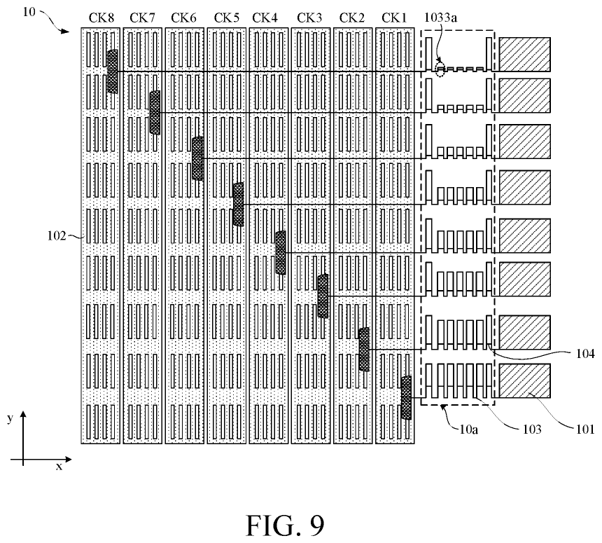

Optionally, refer to FIG. 9. FIG. 9 is a schematic diagram of a third structure of an array substrate according to an embodiment of the present disclosure. Each bent connection line 1033 includes a plurality of bent units 1033a connected in sequence. The bent units 1033a are respectively connected to the first connection line 1031 and the second connection line 1032 using traces. At least one parallel trace 104 is further connected to the bent unit 1033a. The parallel trace 104 and the bent connection line 1033 are disposed in parallel. It may be understood that, in the array substrate 10 provided in the embodiment of the present disclosure, the bending manner of the bent connection line 1033 may be zigzag, serpentine, in a pulse form, in a concave-convex broken line, wave-shaped, or sawtooth. For example, the bent connection line 1033 in the bent unit 1033a has two traces extending in the first direction, and the two traces are connected by traces extending in the second direction. By means of these bending forms, a longer communication line 103 can be bent in a smaller space, thereby saving the arrangement space of the communication line 103, and facilitating the narrowing of the frame of the panel. In FIG. 9, the bent connection line 1033 is bent into a pulse shape as illustration.

Optionally, in some embodiments, the bending lengths of the plurality of first connection lines 1031 are all same as that of the plurality of second connection lines 1032, and the lengths of the first connection lines 1031 are greater than the length of the bent unit 1033a. If the lengths of the first connection lines 1031 are greater than the length of the bent unit 1033a, the first connection lines 1031 and the bent connection line 1033 in the bent unit 1033a can be arranged in a staggered manner, so as to reduce the risk of short circuits of the first connection lines 1031 and the bent connection line 1033.

Optionally, one parallel trace 104 is connected to the bent connection line 1033. The parallel trace 104 and the bent connection line 1033 are disposed in parallel. Since the communication lines 103 in different rows are designed in different bending ways in the winding area 10a, uneven etching may occur during the manufacturing. Therefore, the etching uniformity can be improved by connecting the parallel trace 104 in the middle. The design of the parallel trace 104 is equivalent to connecting a resistance line in parallel with the bent connection line 1033. The connection position of the parallel trace 104 is adjusted to ensure that the resistance values of the communication lines 103 remains unchanged, and the winding length of the communication lines 103 is also increased, thereby improving the etching uniformity to a certain extent. In addition, the addition of the parallel trace 104 can also improve the connection stability of the bent connection line 1033. In order to prevent the width of the frame of the non-display area of the display panel from being increased, the width of the winding area 10a should not be too large. The area for the bending design of the bent connection line 1033 in the winding area 10a is smaller, and a distance between adjacent bent connection lines 1033 is smaller, easily causing open circuits during etching. At least one parallel trace 104 is connected to the bent connection line 1033, so as to avoid the problem that the signal cannot be transmitted after a section of the communication line 103 is open.

It should be noted that, under the condition that the length of the communication line 103 remains unchanged, a quantity of parallel traces 104 can be increased in an area with denser wiring. For example, the length of the bent connection line 1033 of the communication line 103 of CK8 is relatively small, and the bending density in the winding area 10a is relatively small, so that the quantity of parallel traces 104 can be reduced. The length of the bent connection line 1033 of the communication line 103 of CK1 is relatively large, and the bending density in the winding area 10a is relatively large, so that the quantity of parallel traces 104 can be increased.

Optionally, a quantity of bending columns of the communication lines 103 can be considered according to lateral distances. There is no fixed standard and range for the lateral distance, which require to be considered comprehensively based on factors such as a resolution, a quantity of clock signal lines 102, and the like. Since in a high-resolution panel, the slight difference between the clock signals of the GOA has a greater impact on the pixel display, and a larger quantity of clock signal lines 102 leads to a larger difference value in the lateral capacitances, a larger quantity of clock signal lines 102 leads to a decrease in the distance between the clock signal lines 102. That is to say, the bending length of the communication lines 103 is larger, and the area of the communication lines laterally directly facing the clock signal lines becomes larger. At this point, the width of the winding area 10a requires to be reduced. That is to say, the quantity of bending columns of the communication lines 103 is reduced. Therefore, optionally, the quantity of clock signal lines 102 is inversely proportional to the quantity of bending columns of the communication lines 103.

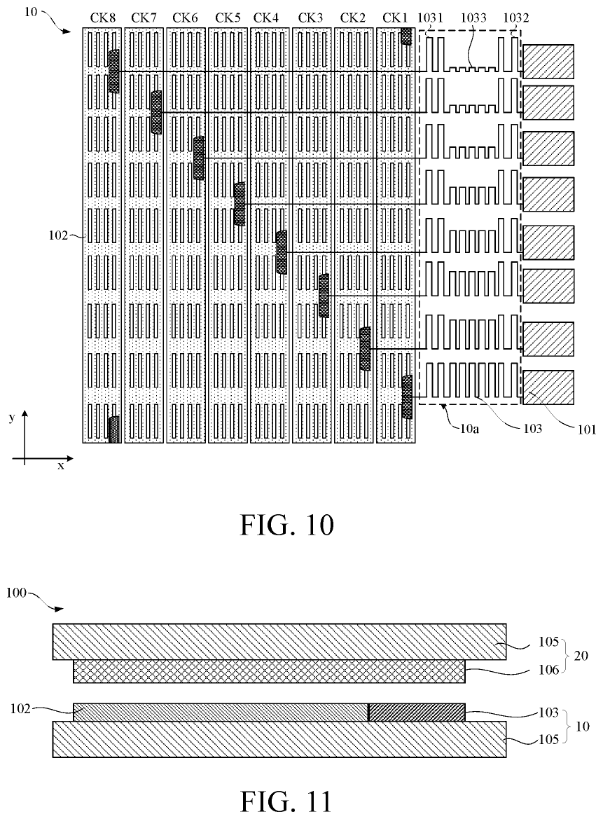

Optionally, each communication line 103 includes a first connection line 1031, a second connection line 1032, and a bent connection line 1033. In some embodiments, each communication line 103 includes two first connection lines 1031 disposed adjacent to each other, two second connection lines 1032 disposed adjacent to each other, and a bent connection line 1033. In detail, refer to FIG. 10. FIG. 10 is a schematic diagram of a fourth structure of an array substrate according to an embodiment of the present disclosure. In the embodiment shown in FIG. 10, in the winding area 10a, the bending lengths of the first connection lines 1031 or the second connection lines 1032 are same. That is to say, in the embodiment of the present disclosure, no limitations are imposed on the quantity of the bending columns, the bending length, the bending area, and the bending density of the communication lines 103 for matching the lateral capacitances. The communication lines 103 on a same side have a same bending length, so as to alleviate the problem of uneven lateral capacitances.

Correspondingly, an embodiment of the present disclosure further provides a display panel. Refer to FIG. 11, FIG. 11 is a schematic diagram of a structure of a display panel according to an embodiment of the present disclosure. A display panel 100 includes an array substrate 10 and a counter substrate 20. The array substrate 10 is the array substrate 10 described above. The array substrate includes a substrate 105, clock signal lines 102, and communication lines 103. The counter substrate 20 is disposed opposite to the array substrate 10. The counter substrate 20 includes the substrate 105, and an electrode 106 is disposed corresponding to the communication lines 103 and the clock signal lines 102 on the counter substrate 20.

In the display panel 100 provided in the embodiment of the present disclosure, the communication lines 103 are disposed on the array substrate 10. The communication lines 103 have a same bending length on a same side of the winding area, which equalizes the lateral capacitances of the communication lines 103 in different rows. In addition, due to the bending design of the communication lines 103 close to the central axis of the winding area, the capacitance between the communication lines 103 and the electrode 106 in different rows can be balanced, thereby compensating for the capacitance between the communication lines 103 and the electrode 106.

It should be noted that, the array substrate 10 and the counter substrate 20 may further include other devices. The other devices and the assembling are the technology well known to those skilled in the art, and details are not described herein again.

An embodiment of the present disclosure provides a display panel. The display panel includes an array substrate and a counter substrate. According to the array substrate in the display panel provided in the embodiment of the present disclosure, a winding design is performed for the communication lines disposed on the array substrate. The plurality of communication lines have a same length, and a winding area is provided between the clock signal lines and the GOA units. The communication lines are bent in the winding area. In the winding area, bending lengths of the plurality of communication lines that are on at least one side close to the clock signal lines or close to the GOA units are equal. In the winding area, bending lengths of the communication lines on at least one side close to the clock signal lines or close to the GOA units are designed to be equal, so that the lateral capacitances of the communication lines on the at least one side can match. In this way, the problem that the lateral capacitances generated by the communication lines in different rows and surrounding traces are different is resolved. Moreover, the communication lines are wound in the winding area, so that total lengths of the communication lines in different rows are same, and the problem of differences in resistances and capacitances of the communication lines in different rows is also resolved. In the display panel provided in the embodiment of the present disclosure, by means of the design of the bending method of the communication lines, the problem of the open and concealed lines of the panel can be improved.

The array substrate and the display panel provided in the embodiments of the present disclosure are described in detail above. The principles and implementations of present disclosure are described by using specific examples in this specification, and the descriptions of the embodiments are only intended to help understand the methods and core ideas of the present disclosure. Meanwhile, a person skilled in the art may make modifications to the specific implementations and application scopes according to the ideas of the present disclosure. In conclusion, the content of this specification should not be construed as a limitation to the present disclosure.

What is claimed is:

1. An array substrate, comprising:
a plurality of gate on array (GOA) units;
a plurality of clock signal lines disposed on a side of the GOA units and arranged in sequence in a first direction; and
a plurality of communication lines, wherein one of the communication lines is correspondingly connected to one of the clock signal lines and one of the GOA units, and wherein
a winding area is provided between the clock signal lines and the GOA units, each communication line comprises a first part, a winding part, and a second part connected in sequence, the first part is connected to one of the clock signal lines, the second part is connected to one of the GOA units, and the winding part is disposed in the winding area;
the winding part comprises a plurality of first connection lines, a plurality of second connection lines, and a plurality of bent connection lines, each bent connection line connects between one of the first connection lines and one of the second connection lines, each first connection line is disposed opposite to one of the clock signal lines, and each second connection line is disposed opposite to one of the GOA units; and
lateral capacitances formed by the plurality of first connection lines and the clock signal lines are equal, and/or lateral capacitances formed by the plurality of second connection lines and the GOA units are equal.

2. The array substrate as claimed in claim 1, wherein in a second direction that intersects with the first direction, the plurality of first connection lines have a same length, and/or the plurality of second connection lines have a same length.

3. The array substrate as claimed in claim 1, wherein in the first direction, distances between the plurality of first connection lines and the clock signal lines are equal, and/or distances between the plurality of second connection lines and the GOA units are equal.

4. The array substrate as claimed in claim 1, wherein the plurality of communication lines have a same length.

5. The array substrate as claimed in claim 1, wherein each first connection line comprises a first trace, a second trace, and a third trace, the first trace is disposed on a side away from the bent connection lines, the second trace is spaced apart from the first trace, the second trace is connected to the bent connection line, the third trace is connected between the first trace and the second trace, and the first trace and the second trace have a same length or different lengths.

6. The array substrate as claimed in claim 1, wherein the each second connection line comprises a first wire, a second wire, and a third wire, the first wire is disposed on a side away from the each bent connection line, the second wire and the first wire are disposed in parallel and spaced apart by a spacing, the second wire is connected to the each bent connection line, the third wire is connected between the first wire and the second wire, and the first wire and the second wire have a same length or different lengths.

7. The array substrate as claimed in claim 1, wherein each communication line comprises one of the first connection lines, one of the second connection lines, and one of the bent connection lines.

8. The array substrate as claimed in claim 1, wherein each communication line comprises at least two of the first connection lines, at least two of the second connection lines, and one of the bent connection lines.

9. The array substrate as claimed in claim 1, wherein each bent connection line comprises a plurality of bent units connected in sequence, and the bent units are respectively connected to the first connection lines and the second connection lines by traces.

10. The array substrate as claimed in claim 9, wherein at least one parallel trace is further connected to the bent units, and the parallel trace is disposed in parallel with each bent connection line.

11. The array substrate as claimed in claim 1, wherein each clock signal line is connected to the plurality of communication lines, and a set of the communication lines comprising at least one communication line are connected to the clock signal lines in sequence in a direction in which the clock signal lines are arranged.

12. The array substrate as claimed in claim 11, wherein in each set of the communication lines, in a second direction that intersects the first direction, the first parts are increasingly enlarged and bending lengths of the bent connection lines are gradually shortened.

13. The array substrate as claimed in claim 11, wherein in each set of the communication lines, in a second direction that intersects the first direction, the first parts are increasingly enlarged and bending spacings between the bent connection lines are gradually shortened.

14. A display panel, comprising:
an array substrate comprising a plurality of GOA units, a plurality of clock signal lines, and a plurality of communication lines, wherein the plurality of clock signal lines are disposed on a side of the GOA units and are arranged in sequence in a first direction, wherein one of the communication lines is correspondingly connected to one of the clock signal lines and one of the GOA units, and wherein
a winding area is provided between the clock signal lines and the GOA units, each communication line comprises a first part, a winding part, and a second part connected in sequence, the first part is connected to one of the clock signal lines, the second part is connected to one of the GOA units, and the winding part is disposed in the winding area;
the winding part comprises a plurality of first connection lines, a plurality of second connection lines, and a plurality of bent connection lines, each bent connection line connects between one of the first connection lines and one of the second connection lines, each first connection line is disposed opposite to one of the clock signal lines, and each second connection line is disposed opposite to one of the GOA units; and
lateral capacitances formed by the plurality of first connection lines and the clock signal lines are equal, and/or lateral capacitances formed by the plurality of second connection lines and the GOA units are equal; and
a counter substrate disposed opposite to the array substrate, wherein electrodes are disposed on the counter substrate corresponding to the communication lines and the clock signal lines.

15. The display panel as claimed in claim 14, wherein in a second direction that intersects with the first direction, the plurality of first connection lines have a same length, and/or the plurality of second connection lines have a same length.

16. The display panel as claimed in claim 14, wherein in the first direction, distances between the plurality of first connection lines and the clock signal lines are equal, and/or distances between the plurality of second connection lines and the GOA units are equal.

17. The display panel as claimed in claim 14, wherein each first connection line comprises a first trace, a second trace, and a third trace, the first trace is disposed on a side away from the bent connection lines, the second trace is spaced apart from the first trace, the second trace is connected to the bent connection line, the third trace is connected between the first trace and the second trace, and the first trace and the second trace have a same length or different lengths.

18. The display panel as claimed in claim 14, wherein the each second connection line comprises a first wire, a second wire, and a third wire, the first wire is disposed on a side away from the each bent connection line, the second wire and the first wire are disposed in parallel and spaced apart by a spacing, the second wire is connected to the each bent connection line, the third wire is connected between the first wire and the second wire, and the first wire and the second wire have a same length or different lengths.

19. The display panel as claimed in claim 14, wherein each bent connection line comprises a plurality of bent units connected in sequence, and the bent units are respectively connected to the first connection lines and the second connection lines by traces.

20. The display panel as claimed in claim 19, wherein at least one parallel trace is further connected to the bent units, and the parallel trace is disposed in parallel with each bent connection line.
